(19) United States
(12) Patent Application Publication
(10) Pub. No.: US 2017/0271625 A1
(43) Pub. Date: Sep. 21, 2017

(54) METHOD FOR FORMING DISPLAY SUBSTRATE FOR DISPLAY PANEL

(71) Applicant: BOE TECHNOLOGY GROUP CO., LTD., Beijing (CN)

(72) Inventors: LU LIU, Beijing (CN); MING CHE HSIEH, Beijing (CN); BAOMING CAI, Beijing (CN)

(73) Assignee: Boe Technology Group Co., Ltd., Beijing (CN)

(21) Appl. No.: 15/305,497

(22) PCT Filed: Sep. 28, 2015
(86) PCT No.: PCT/CN2015/090915

§ 371 Date: Oct. 20, 2016

(51) Int. Cl. H01L 51/56; H01L 27/32; H01L 21/768

(52) U.S. Cl. CPC H01L 51/56; H01L 21/76867; H01L 27/3274; H01L 2251/5338

(57) ABSTRACT

The present disclosure provides a method for fabricating a display substrate for a display panel. The method includes providing a flexible organic light-emitting diode (flexible OLED) substrate with a thin-film transistor (TFT) layer on the flexible OLED substrate and a patterned adhesive layer on the TFT layer, wherein the TFT layer includes at least one testing area; providing a barrier film (BF) with a patterned laser barrier layer on a surface of the BF, the surface of the BF facing the TFT layer; and bonding the BF onto the flexible OLED substrate such that at least a portion of the patterned laser barrier corresponds to the at least one testing area. The method also includes irradiating a laser beam along a cutting line on the BF to remove a first portion of the BF.

### FIELD OF THE INVENTION

The present invention generally relates to the display technologies and, more particularly, relates to a method for forming a display substrate for display panels.

### BACKGROUND

Organic light-emitting diode (OLED) devices are widely used at the present time. Among various OLED devices, manufactures have shown great interest in flexible OLED devices and have produced various flexible OLED devices.

As shown in FIG. 1, a flexible OLED display panel often includes multiple films or layers such as a barrier film (BF), an organic layer (not shown), an adhesive layer, a thin-film transistor (TFT) layer, a flexible substrate, and a substrate. During the fabrication process for forming a flexible OLED display panel, laser cutting is often used to remove certain portions of one or more films on the substrate so that certain components on the substrate can be exposed for testing. Carbon dioxide laser has been commonly used in the laser cutting process to remove portions of certain films on a substrate.

The laser cutting process often includes a full cutting process and a half cutting process, as shown in FIG. 1. The full cutting process refers to cutting off or removing portions of all the films or layers on the substrate until the glass substrate is exposed. The half cutting process refers to only cutting off portions of some, but not all, films or layers to expose portions of certain films or layers on the substrate. For example, as shown in FIG. 1, a half cutting process may be used to remove portions of the BF film to expose portions of the TFT layer for testing. The half cutting process should not damage the TFT layer under the films. The laser energy is thus adjusted and controlled to accommodate the depth of the laser cutting process.

However, the films on a substrate are generally very thin. Even laser energy only slightly higher than what is needed for the cutting process may cause damages to the layer to be exposed (e.g., TFT layer). As a result, using the conventional laser cutting technology, the process window can be relatively narrow. Further, adjusting the laser energy to a proper level may consume a great amount of time and cutting samples, which can be costly. Furthermore, even if the laser energy level is properly set, a small fluctuation of the energy level may also cause damages to the to-be-exposed layer (e.g., TFT layer).

### BRIEF SUMMARY OF THE DISCLOSURE

The present disclosure provides a method for forming a display substrate, e.g., a flexible OLED structure. The disclosed method can be implemented to fabricate the flexible OLED structure and may prevent a TFT layer from being damaged during the laser cutting process. In embodiments of the present disclosure, the adjustable processing window of the fabrication process can be improved, and the fabrication cost of the flexible OLED display panel can be reduced.

One aspect of the present disclosure provides a method for fabricating a display substrate for a display panel. The method includes providing a flexible organic light-emitting diode (flexible OLED) substrate with a thin-film transistor (TFT) layer on the flexible OLED substrate and a patterned adhesive layer on the TFT layer, wherein the TFT layer includes at least one testing area; providing a barrier film (BF) with a patterned laser barrier layer on a surface of the BF, the surface of the BF facing the TFT layer; and bonding the BF onto the flexible OLED substrate such that at least a portion of the patterned laser barrier corresponds to the at least one testing area. The method also includes irradiating a laser beam along a cutting line on the BF to remove a first portion of the BF from a second portion of the BF.

Optionally, irradiating the laser beam to remove the first portion of the BF includes irradiating the laser beam along the cutting line to melt a portion the BF along the cutting line; detaching the first portion of the BF from the second portion of the BF, the first portion of the BF being associated with the testing area; and removing the first portion of the BF from the second portion of the BF to expose the at least one testing area on the TFT layer.

Optionally, the at least a portion of the patterned laser barrier layer is formed on the first portion of the BF.

Optionally, a void space is formed between a portion of the patterned adhesive layer and the at least one testing area.

Optionally, the patterned laser barrier layer is made of a material reflective to the laser beam.

Optionally, the laser beam is a carbon dioxide laser beam and the patterned laser barrier layer is reflective of a wavelength of the carbon dioxide laser beam.

Optionally, the patterned laser barrier layer is formed by a deposition process, a spin-on coating process, a bonding process, or a combination thereof

Optionally, the pattern adhesive layer does not cover the at least one testing area on the TFT layer.

Optionally, the patterned laser barrier is made of Cu, Al, or a combination of Cu and Al.

Optionally, the patterned laser barrier layer has a thickness of about 8 nm to about 1 μm.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates the cross-sectional view of a portion of a flexible OLED structure for a flexible OLED display panel;

FIG. 2 illustrates a cross-sectional view of a portion of the flexible OLED structure according to the disclosed embodiments of the present disclosure;

FIG. 3 illustrates another cross-sectional view of the portion of the flexible OLED structure according to the disclosed embodiments of the present disclosure; and

FIG. 4 illustrates another cross-sectional view of the portion of the flexible OLED structure according to the disclosed embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

One aspect of the present disclosure provides a flexible OLED structure for a half cutting process.

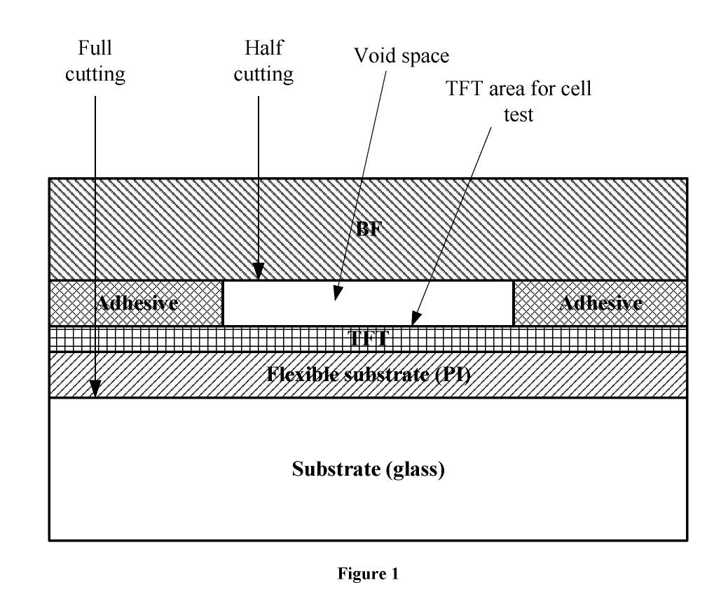

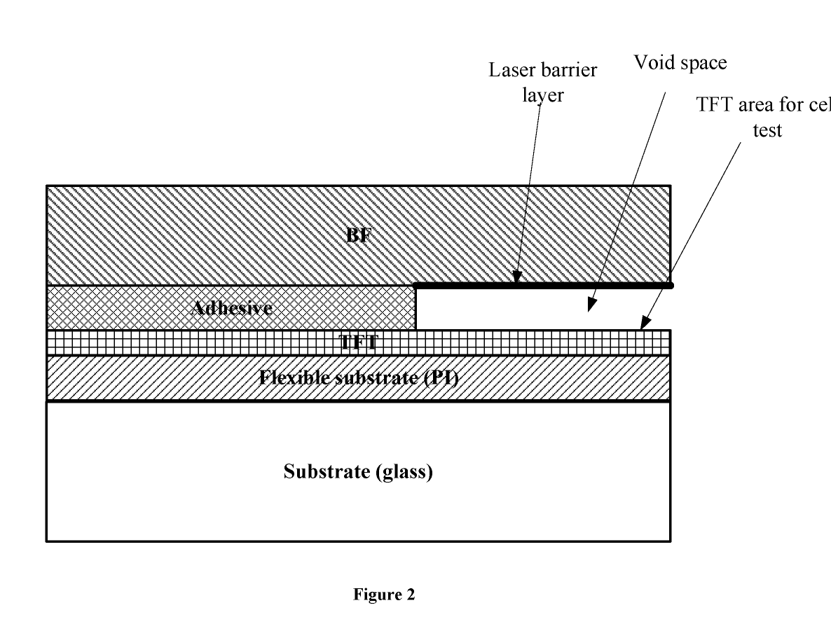

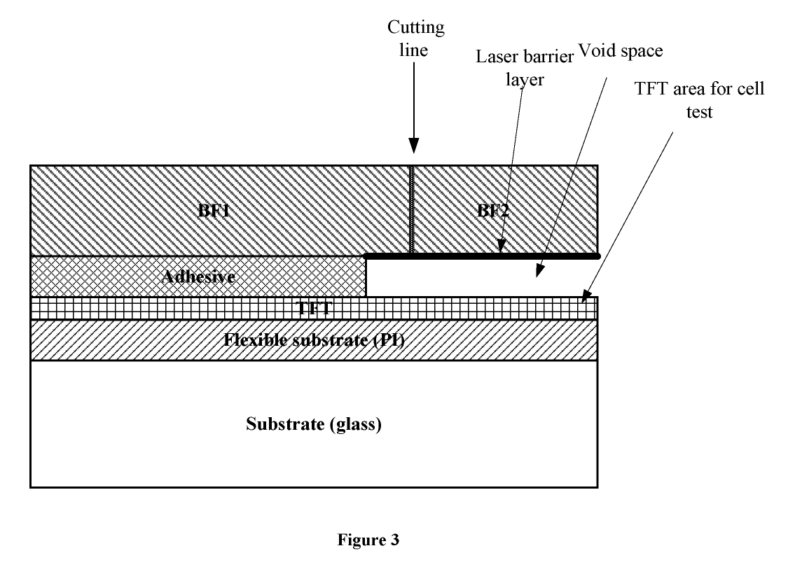

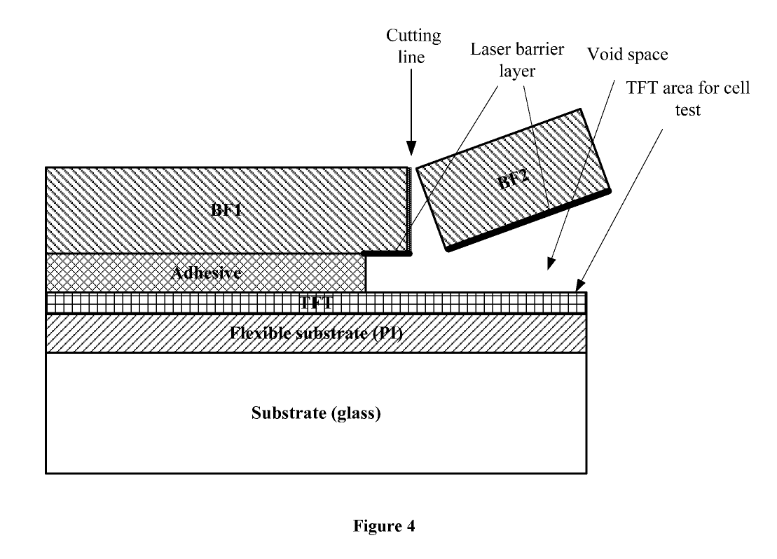

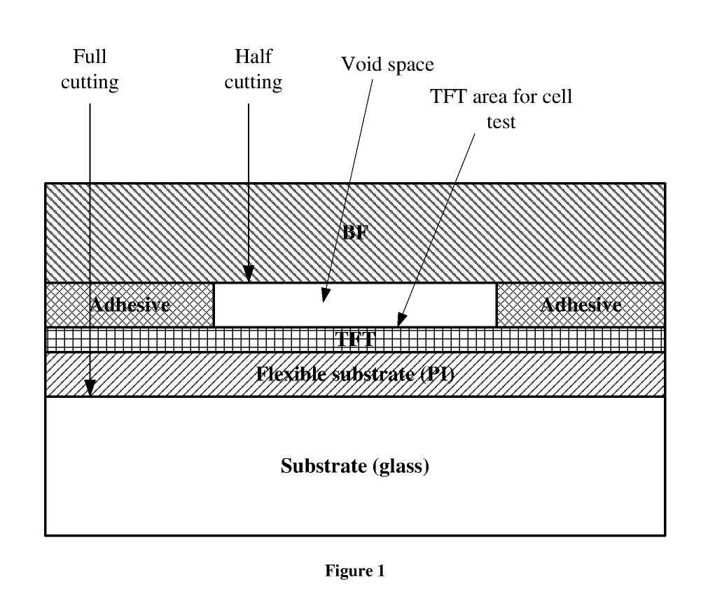

FIG. 1 illustrates the cross-sectional view of a portion of a flexible OLED structure for forming a flexible OLED display panel. The flexible OLED structure may include a BF, an adhesive layer, a TFT layer, a flexible substrate, and a stiff substrate. The stiff substrate may be made of glass for supporting the flexible substrate and the layers and components formed on the flexible substrate during the fabrication and testing processes. The stiff substrate may be removed in subsequent processing steps. The flexible substrate may be formed on the stiff substrate, and may be made of polyimide (PI). On the flexible substrate, the TFT layer may be formed. An organic layer (not shown) and corresponding electrode layers (not shown) may be formed on the TFT layer to form a plurality of OLEDs for emitting light. The TFT layer may include a plurality of TFTs and at least some of the TFTs are connected to the OLEDs for controlling and driving the OLEDs. For viewing simplicity, the OLEDs and the electrode layers are not shown in the figures. An adhesive layer, often patterned, may be formed on certain portions of the TFT layer to attach to or with bond the BF. The adhesive may be any suitable adhesive such as glue. The BF may be a plastic film or plate with high transparency. The BF may be used to prevent certain components of the display panel, e.g., the TFT layer and the OLEDs, from being exposed to oxygen and moisture.

In practice, certain areas on the TFT layer are designed for testing. After the testing, the display panel may be processed for subsequent operations. Thus, the areas on the TFT layer for testing (e.g., cell test) may not be covered with the adhesive layer. In other words, the adhesive layer may be patterned to leave the areas for cell test uncovered. When the BF is bonded onto the adhesive layer, void spaces may be formed between the BF and the areas for cell test, as shown in FIG. 1.

In the fabrication process of a flexible OLED display panel, the BF above certain TFT areas for cell test may be removed for the subsequent the testing process. Thus, a half cutting process by laser cutting may be used to remove the portions of the BF at the desired locations. After the portions of the BF are removed, the TFT areas for cell test would be exposed.

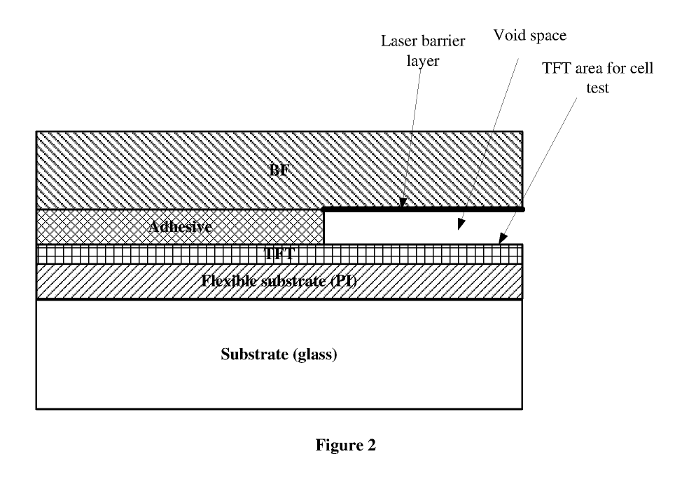

FIG. 2 illustrates the flexible OLED structure according to the present disclosure. The flexible OLED structure may have at least one TFT areas for cell test. For viewing simplicity, FIG. 2 only shows a portion of the flexible OLED structure shown in FIG. 1.

As shown in FIG. 2, the flexible OLED structure may further include a laser barrier layer on the back surface of the BF. The back surface of the BF may refer to the surface of the BF facing the TFT layer or bonded with the adhesive layer. The laser barrier layer may be a patterned film on the back surface of the BF. Only the areas on the back surface of the BF corresponding to the TFT areas for cell test are deposited with the laser barrier layer. The laser barrier layer may have a thickness of about 8 nm to about 1 μm. A portion of the laser barrier layer is shown as the thick black line in FIG. 2.

As shown in FIG. 2, an adhesive layer may be formed on the TFT layer or the organic layer. The adhesive layer may be patterned to leave the TFT areas for cell test exposed. The BF may be placed on the adhesive layer to cover the TFT areas for cell test. The BF may be a plastic plate or film with high transparency. Because of the stiffness of the BF layer, void spaces may be formed between the back surface of the BF and the top surface of the TFT layer.

The laser barrier layer may be patterned on the back surface of the BF. The back surface of the BF may refer to the surface of the BF facing the TFT layer and flexible substrate. Only the areas on the back surface of the BF corresponding to the TFT areas for cell test may be deposited with the laser barrier layer, as shown in FIG. 2. The laser barrier layer may be made of any suitable material capable of reflecting the laser used in the laser cutting process. For example, the laser barrier layer may be made of metals such as Cu and/or Al.

When in operation, carbon dioxide laser may be used in the half cutting process to remove the desired portion of BF above the TFT layer for cell test. The wavelength of the carbon dioxide laser may be about 9.3 μm. The laser beam may move alone a cutting line to remove the desired portion of BF. Heat generated from the contact between the laser beam and the desired portions of BF may melt the BF along the cutting line so that the desired portion of BF may be disconnected or detached. The disconnected portion of the BF may be fully removed from the rest of the BF subsequently by a mechanical force. Meanwhile, when the carbon dioxide laser is illuminated on the cutting line, the wavelength may be reflected back into the BF and being absorbed because of the high reflectivity of the laser barrier layer. Thus, the portion of the BF along the cutting line may be melted and the TFTs under the BF are protected from being damaged by the laser. Because of the high reflectivity of the laser barrier layer, fluctuations in the energy level of the laser beam may not cause any damage to the TFT layer.

It should be noted that the laser beam for the half cutting process may also be of other suitable wavelengths. For example, the laser beam may be an ultraviolet (UV) laser. In this case, the material of the laser barrier layer may be any suitable material capable of reflecting UV light. The type of laser and the material of the laser barrier layer should not be limited by the specific embodiments of the present disclosure.

After the portion of the BF is removed, certain tests may be done on the cell test area of the TFT layer, and the flexible OLED structure may be processed following subsequent steps.

Another aspect of the present disclosure provides a method for forming the flexible OLED structure.

First, a patterned laser barrier layer is formed on a back surface of a BF.

The laser barrier layer may be made of any suitable material capable of reflecting the wavelength of the laser beam used for half cutting. The patterned laser barrier layer may be formed through any suitable process. For example, the patterned laser barrier layer may be formed by selective epitaxial deposition, by a spin-on coating process, or by a gluing or bonding process. The patterned laser barrier layer may also be formed by patterning a deposited film on the back surface of the BF by photolithography followed by an etching process. In some embodiments, the laser barrier layer may be a metal tape attached onto the back surface of the BF. The areas deposited with the reflective material may correspond to the TFT areas for cell test. In one embodiment, the reflective material may be Cu deposited through a spin-on coating process.

Further, a flexible OLED substrate with patterned adhesive layer is formed on the top surface of a TFT layer.

The flexible OLED substrate may include a stiff substrate, a flexible substrate, a TFT layer, an organic layer, and related electrode layers. The stiff substrate may be made of glass. The flexible substrate may be made of polyimide and formed on the stiff substrate. The TFT layer, the organic layer and the related electrode layers may be formed on the flexible substrate.

A patterned adhesive layer may be formed on the TFT layer. The patterned adhesive layer may be formed through any suitable process such as a spin-on coating process. The adhesive layer may be made of any suitable materials capable of attaching or bonding the BF onto the flexible OLED substrate, such as glue. The adhesive layer may also be adhesive tapes. The adhesive layer may be patterned to leave the TFT areas for cell test uncovered. The patterning process and the thickness of the adhesive layer may be determined according to different applications or designs and are not limited by the embodiments of the present disclosure. In one embodiment, the patterned adhesive layer may be made of glue.

It should be noted that the process to form the patterned laser barrier layer and the process to form the patterned adhesive layer may be implemented simultaneously or at different times. One process may be implemented before the other, or vice versa.

No specific order is required.

Further, the BF is bonded onto the flexible OLED substrate so that the laser barrier layer is facing the TFT layer for cell test.

The BF may be bonded onto the flexible OLED substrate through the adhesive layer with the back surface of the BF facing the TFT layer. The areas on the back surface of the BF deposited with the reflective material of the laser barrier layer may correspond to the TFT areas for cell test and at least substantially cover the TFT areas for cell test. Void spaces may be formed between the front surface of the TFT area for cell test and the corresponding back surface of the BF with the reflective material. Certain pressing process may be used to enhance the adhesion or bonding the BF and the adhesive layer. The cross-sectional view of the formed flexible OLED structure, after the BF is bonded onto the flexible OLED substrate, is shown in FIG. 2.

Further, a laser cutting process is performed to detach or disconnect at least a portion of the BF, corresponding to the TFT area for cell test, from the rest of the BF.

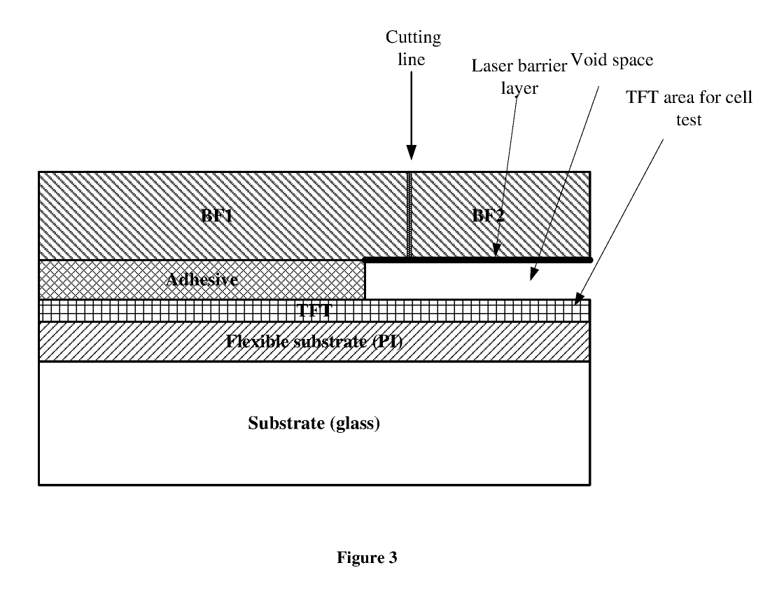

As shown in FIG. 3, the laser beam, e.g. a carbon dioxide laser beam, may be irradiated on a cutting line and move along the cutting line until the desired portion of the BF is detached from the rest of the BF. The cutting line may be used to define the portion of the BF to be removed. For illustrative purposes, the portion of BF to be removed is referred to as BF2 in FIG. 3. The portion of BF to be kept on the adhesive layer is referred to as BF1 in FIG. 3.

The position of the cutting line may be determined or adjusted according to different applications or designs such that at least a portion of the TFT area for cell test can be exposed. The energy level of the laser beam and the irradiation duration may also be determined or adjusted according to different applications or designs. In one embodiment, the carbon dioxide laser with a cutting speed of about 80 to 200 mm per second and laser current of about 2% to about 10% may be used to irradiate on the cutting line. When irradiating on the cutting line, the laser beam may be reflected by the laser barrier layer and dispersed in the BF. The reflected laser beam may be absorbed by the BF and thus may not irradiate onto the corresponding TFT layer to cause damages. The TFT layer may thus be kept less damaged or undamaged during the laser cutting process.

Further, the portion of the BF corresponding to the TFT areas for cell test is detached from the rest of the BF to expose the corresponding TFT areas for cell test.

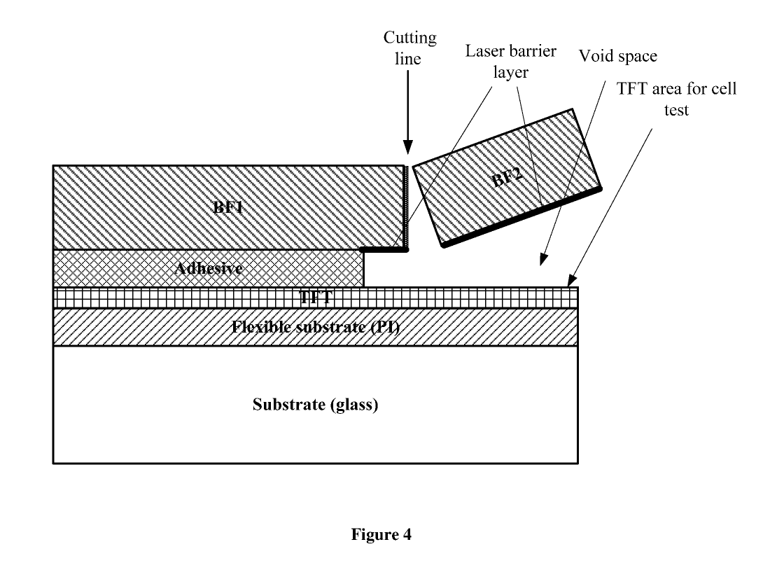

As shown in FIG. 4, BF2 may be detached or removed from the BF1. Any suitable process, such as a mechanical process, may be used to remove BF2. The corresponding TFT area below the void space may be exposed for subsequent cell test.

By using the disclosed flexible OLED structure, a patterned reflective laser barrier layer may be formed on the back surface of the BF. The portions of the BF deposited with the reflective material may correspond to TFT areas for cell test. Thus, in a half cutting process, the laser beam may be reflected back to the BF by the laser barrier layer such that the TFT areas for cell test may not be damaged by the laser beam. The TFT areas would also not be damaged by any fluctuation in the energy level of the laser beam. The process window of the fabrication can be greatly improved or widened, and fabrication cost may be reduced.

Another aspect of the present disclosure provides a display panel. The display panel may incorporate the disclosed flexible OLED structure.

Another aspect of the present disclosure provides a display apparatus. The display apparatus may incorporate one or more of the above-mentioned display panels. The display apparatus according to the embodiments of the present disclosure can be used in any product with display functions such as a television, an electronic paper, a digital photo frame, a mobile phone and a tablet computer.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-10. (canceled)

11. A method for fabricating a display substrate for a display panel, including:
providing a flexible organic light-emitting diode (flexible OLED) substrate with a thin-film transistor (TFT) layer on the flexible OLED substrate and a patterned adhesive layer on the TFT layer, wherein the TFT layer includes at least one testing area;
providing a barrier film (BF) with a patterned laser barrier layer on a surface of the BF, the surface of the BF facing the TFT layer;
bonding the BF onto the flexible OLED substrate such that at least a portion of the patterned laser barrier corresponds to the at least one testing area; and
irradiating a laser beam along a cutting line on the BF to remove a first portion of the BF from a second portion of the BF.

12. The method according to claim 11, wherein irradiating the laser beam to remove the first portion of the BF includes:
irradiating the laser beam along a the cutting line to melt a portion the BF along the cutting line;
detaching the first portion of the BF from the second portion of the BF, the first portion of the BF being associated with the testing area; and
removing the first portion of the BF from the second portion of the BF to expose the at least one testing area on the TFT layer.

13. The method according to claim 11, wherein the at least a portion of the patterned laser barrier layer is formed on the first portion of the BF.

14. The method according to claim 11, wherein a void space is formed between a portion of the patterned adhesive layer and the at least one testing area.

15. The method according to claim 11, wherein the patterned laser barrier layer is made of a material reflective to the laser beam.

16. The method according to claim 15, wherein the laser beam is a carbon dioxide laser beam and the patterned laser barrier layer is reflective of a wavelength of the carbon dioxide laser beam.

17. The method according to claim 11, wherein the patterned laser barrier layer is formed by a deposition process, a spin-on coating process, a bonding process, or a combination thereof.

18. The method according to claim 11, wherein the pattern adhesive layer does not cover the at least one testing area on the TFT layer.

19. The method according to claim 16, wherein the patterned laser barrier is made of Cu, Al, or a combination of Cu and Al.

20. The method according to claim 11, wherein the patterned laser barrier layer has a thickness of about 8 nm to about 1 μm.
